(19) United States
(12) Patent Application Publication
(10) Pub. No.: US 2012/0032266 A1
(43) Pub. Date: Feb. 9, 2012

(54) SEMICONDUCTOR DEVICE AND METHOD OF MANUFACTURING THE SAME

(75) Inventors: Daina INOUE, Yokkaichi (JP); Minori KAJIMOTO, Fujisawa (JP); Tatsuya KATO, Yokkaichi (JP)

(73) Assignee: KABUSHIKI KAISHA TOSHIBA, Minato-ku (JP)

(21) Appl. No.: 13/198,081

(22) Filed: Aug. 4, 2011

(30) Foreign Application Priority Data
Aug. 5, 2010 (JP) 2010-176185

(51) Int. Cl. H01L 27/115; H01L 21/8247

(52) U.S. Cl. 257/365; 438/294; 257/E27.103; 257/E21.68

(57) ABSTRACT

A semiconductor device is disclosed. The semiconductor device includes a semiconductor substrate; a memory cell region defined in the semiconductor substrate; and a line-and-space pattern formed in the memory cell region in which the lines constitute an active region and the spaces constitute an element isolation region. The first and the second lines of the active region counted from two opposing ends of the memory cell region are each separated into two or more line segments. The segment ends of the line segments of the first and the second lines are linked to form a loop by a linking pattern.

### CROSS-REFERENCE TO RELATED APPLICATION(S)

This application is based upon and claims the benefit of priority from Japanese Patent Application No. 2010-176185, filed on, Aug. 5, 2010 the entire contents of which are incorporated herein by reference.

### FIELD

Embodiments disclosed herein generally relate to a semiconductor device and a method of manufacturing the semiconductor device.

### BACKGROUND

Sidewall transfer (SWT) process or sidewall processing is known as one of the methods to form fine sublithographic line and space (L/S) patterns. SWT process is known to allow formation of dense L/S patterns in which both lines and spaces are in the order below several tens of nanometers.

For instance, a NAND flash memory device includes a memory cell region configured by periodic line-and-space patterns where the lines constitute the active regions and the spaces constitute the element isolation regions. When the line-and-space pattern is formed by SWT process, the lines within the memory cell region exclusive of the lines at both lateral ends of the memory cell region are configured such that longitudinal ends of the two neighboring lines are joined by a laterally extending beam so as to define an elongate rectangular loop that are collapse resistant. The lines at both lateral ends of the memory cell region, on the other hand, are arranged into a rectangular loop that serves as the outermost boundary of the memory cell region. The lines at both lateral ends of the memory cell region are thus, substantially isolated from other lines and are collapse prone. Because of such lack of tolerance to collapses, the lines at the lateral ends of the memory cell region were susceptible to collapsing and twisting when the memory cell was being subjected to dry etching and wet processing.

### BRIEF DESCRIPTION OF THE DRAWINGS

FIG. 1 is a schematic plan view partially illustrating a line-and-space pattern formed using a SWT process according to a first embodiment;

FIG. 2 is a schematic plan view partially illustrating a line-and-space pattern formed using a lithography method;

FIGS. 3 to 9 are schematic cross sectional views each indicating one phase of the manufacturing process flow;

FIG. 10 is a schematic plan view partially illustrating a memory cell region according to a second embodiment;

FIG. 11 corresponds to FIG. 10 and illustrates a third embodiment; and

FIG. 12 corresponds to FIG. 10 and illustrates a fourth embodiment.

### DETAILED DESCRIPTION

In one embodiment, a semiconductor device is disclosed. The semiconductor device includes a semiconductor substrate; a memory cell region defined in the semiconductor substrate; and a line-and-space pattern formed in the memory cell region in which the lines constitute an active region and the spaces constitute an element isolation region. The first and the second lines of the active region counted from two opposing ends of the memory cell region are each separated into two or more line segments. The segment ends of the line segments of the first and the second lines are linked to form a loop by a linking pattern.

In one embodiment, a method of manufacturing a semiconductor device is disclosed. The method includes forming a sacrificial film above a semiconductor substrate; forming a resist film above the sacrificial film; patterning the resist film into a first line-and-space pattern in which widths of both the lines and spaces are equal; slimming the width of the lines in half to form a second line-and-space pattern; transferring the second line-and-space pattern to the sacrificial film using the resist film as a mask to forma third line-and-space pattern in the sacrificial film; removing the resist film; forming a sidewall film on sidewalls of the lines of the third line-and-space pattern; and removing the sacrificial film to form a fourth line-and-space pattern; and transferring the fourth line-and-space pattern to the semiconductor substrate using the sidewall film as a mask. Forming the resist film forms one or more cuts in the first line of the first line-and-space pattern counted from opposing ends of an memory cell region of a memory cell to separate the first line into a plurality of segments.

Embodiments are described hereinafter with references to the accompanying drawings to provide illustrations of the features of the embodiments. Elements that are identical or similar are represented by identical or similar reference symbols across the figures and are not redescribed. The drawings are not drawn to scale and thus, do not reflect the actual measurements of the features such as the correlation of thickness to planar dimensions and the relative thickness of different layers.

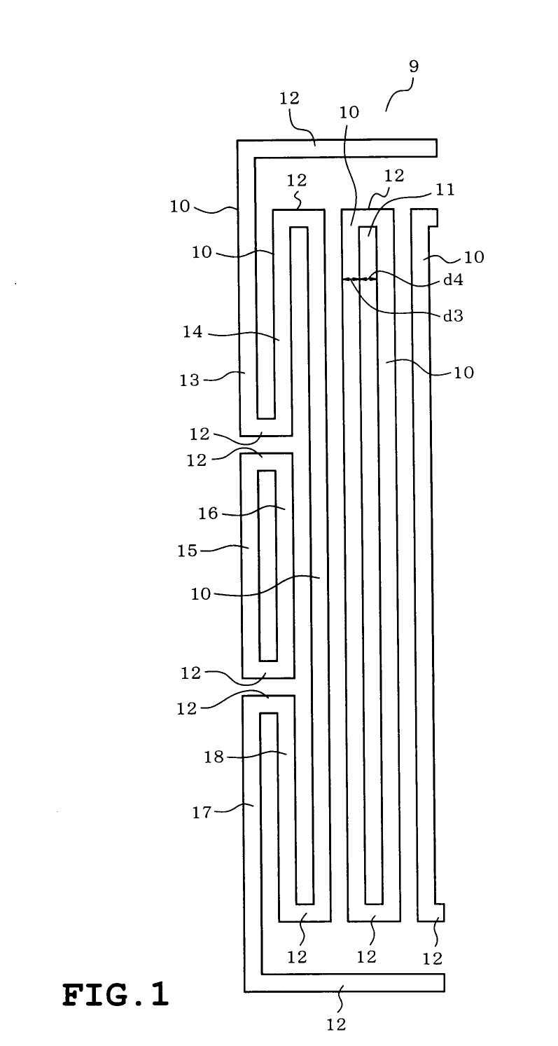

A first embodiment is described hereinafter with reference to FIGS. 1 to 9. According to the first embodiment, a sublithographic line-and-space pattern (L/S pattern), in which the line width is equal to the space width, is formed by a sidewall transfer (SWT) process. Advantageously, the resulting L/S pattern is half the pitch of the L/S pattern formed at the resolution limit of an ordinary lithography process. The sublithographic L/S pattern forms a dense grating in the memory cell region defined in the semiconductor substrate, in which the lines define the active regions and the spaces define the element isolation regions. The memory cell region is also typically referred to as a “plane” where a memory cell array is formed. One or more planes are typically provided in a single chip.

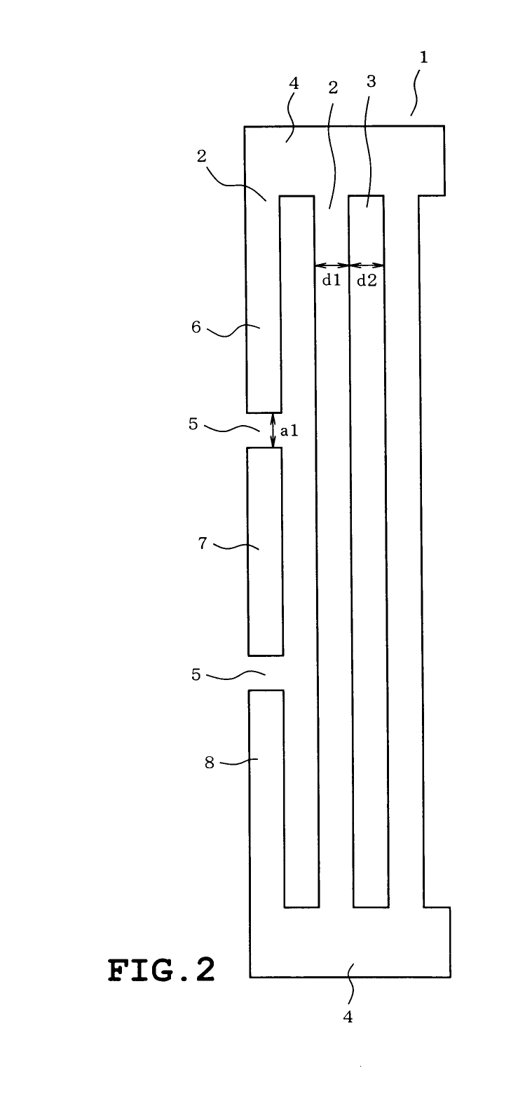

FIG. 2 schematically illustrates resist pattern 1, also referred to as L/S pattern 1 hereinafter, patterned by lines and spaces formed at the resolution limit of a lithography process.

L/S pattern 1 comprises multiplicity of lines 2 and spaces 3 in which width d1 of each line 2 and width d2 of each space are equal. At the longitudinal end of each line 2, linking pattern 4 is formed.

Linking pattern 4 links the longitudinal ends of lines 2 such that the linked lines 2 form a loop. FIG. 2 is a partial illustration of three neighboring lines 2 forming a loop. Because lines 2 are linked into a loop, collapse of lines 2 can be prevented even if dimension d1 and d2 of lines 2 and spaces 3 are as small as several tens of nanometers.

Further, though only the left end line 2 is shown in FIG. 2, the left and right end lines 2 as viewed in FIG. 2 have one or more cuts 5 or gaps that divide/separate line 2 into multiple segments. FIG. 2 exemplifies a case where two cuts 5 are formed. Stated differently, lines 2 residing at the leftmost side and the rightmost side are separated into three line segments 6, 7, and 8 by the two cuts 5. Length al of the gap created by cut 5 as can be seen in FIG. 2 is substantially equal to widths d1 and d2 of lines 2 and spaces 3.

FIG. 1 is a L/S mask pattern 9 obtained by performing a SWT process on resist pattern 1 configured as described above. L/S pattern 9 shown in FIG. 1 comprises multiplicity of lines 10 and spaces 11 in which width d3 of each line 10 and width d4 of each space 11 are equal. Width d3 of line 10 and width d4 of space 11 are half in size compared to width d1 of line 2 and width d2 of space 3.

L/S pattern 9 is configured such that the longitudinal end of each line 10 is linked with the longitudinal end of the neighboring line 10 by linking pattern 12 to form a loop. The width of linking pattern 12 is substantially the same as width d1 of line 10. In the example shown in FIG. 1, the fourth and later lines 10 counted from the left side end of FIG. 1 and the right side end of FIG. 1, though lines counted from the right side end are not shown, are arranged such that two neighboring lines are linked by linking pattern 12 to form an elongate rectangular loop.

The first and the second lines 10 counted from the left side end of FIG. 1 and the right side end of FIG. 1, though lines counted from the right side end are not shown, are each separated into three line segments 13, 15, 17, and 14, 16, 18 as can be seen in comparison with line segments 6, 7, and 8 of resist pattern 1 shown in FIG. 2. The two uppermost line segments 13 and 14 have their lower ends linked together into a loop by linking pattern 12. The upper end of one of the two uppermost line segments, in this case, line segment 13 shown in FIG. 1 is linked with the upper end of the corresponding line segment 13 of the first line 10 counted from the right side end not shown by linking pattern 12 running laterally across the uppermost side of the memory cell region as viewed in FIG. 1. The remaining other uppermost line segment, in this case, line segment 14 has its upper end linked into a loop with the upper end of the third line 10 counted from the left end by linking pattern 12.

The two middle line segments 15 and 16 have both of their longitudinal ends linked together into a loop by linking pattern 12. The two lowermost line segments 17 and 18 have their upper ends linked into a loop by linking pattern 12. One of the two lowermost line segments, in this case, line segment 17 has its lower end linked into a loop with the lower end of the corresponding first line 10 counted from the right side end not shown by linking pattern 12, running laterally across the lowermost side as viewed in FIG. 1. The remaining other lowermost line segment, in this case, line segment 18 has its lower end linked into a loop with the lower end of the third line 10 counted from the left end by linking pattern 12.

According to the first embodiment, L/S pattern 9 shown in

FIG. 1 is transferred to the memory cell region of the semiconductor substrate, where lines 10 correspond to the active regions and spaces 11 correspond to the element isolation trenches.

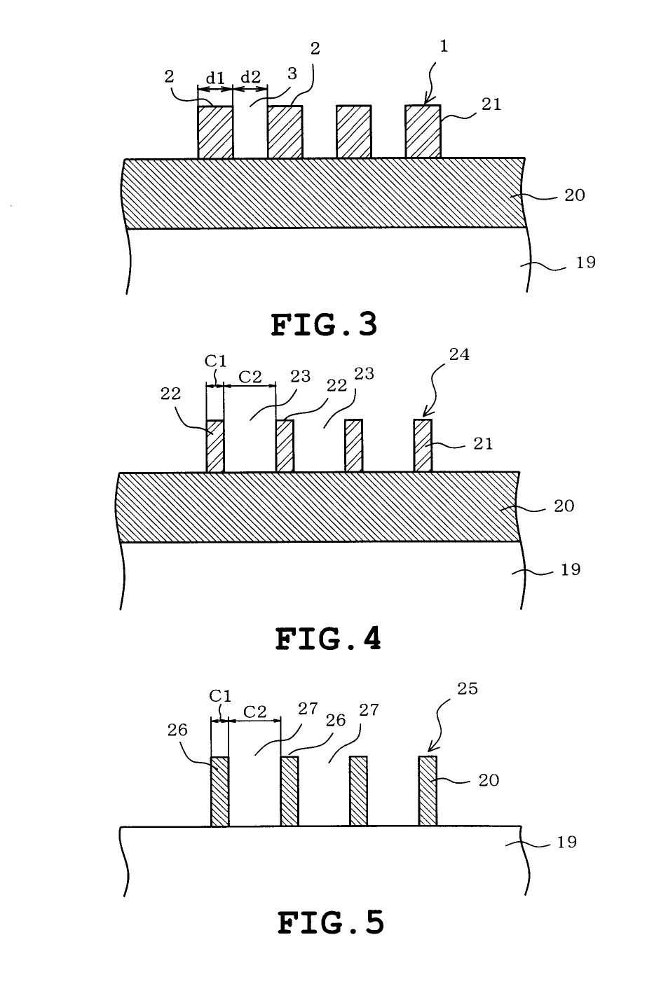

Referring now to FIGS. 3 to 9, a description will be given on a manufacturing process flow for forming element isolation trenches and active regions in a semiconductor substrate based on L/S pattern 9 shown in FIG. 1 through SWT processing of resist pattern 1 shown in FIG. 2.

As shown in FIG. 3, the process flow begins with formation of sacrificial film 20 which may also be referred to as core 20 above a workpiece exemplified as semiconductor substrate 19 in the first embodiment. Sacrificial film 20 may comprise a polysilicon film or amorphous silicon film, or the like. Then, resist film 21 is formed above sacrificial film 20 which is thereafter patterned by lithography to obtain resist pattern 1 of lines and spaces where width d1 of lines 2 and width d2 of spaces are equal at 1:1.

Widths d1/d2 of lines 2/spaces 3 of resist pattern 1 is double the pitch of width d3/d4 of lines 10/spaces 11 of L/S mask pattern 9 shown in FIG. 8. Stated differently, the end result of the process flow is L/S pattern 9 having lines 10/spaces 11 that is half the pitch of widths d1/d2 of lines 2/spaces 3. FIG. 2 is a top view of resist pattern 1 formed at this stage of the process flow, where as FIG. 3 is a cross sectional view of the same.

Next, referring to FIG. 3, resist film 21 is slimmed such that width d1 of lines 2 are halved (½) to width c1 of lines 22 as indicated in FIG. 4. This results in L/S pattern 24 in which width c1 of lines 22 is ⅓ of width c2 of spaces 23.

Then, L/S pattern 24 shown in FIG. 4 is used as a mask for etching sacrificial film 20 by RIE (Reactive Ion Etching) whereafter resist film 21 is removed by ashing to obtain the L/S pattern 25 shown in FIG. 5. As can be seen in FIG. 5, RIE and ashing is controlled such that the transferred lines 26 serving as cores maintain width c1 and the transferred spaces 27 maintain width c2, where width c1 is ⅓ of width c2.

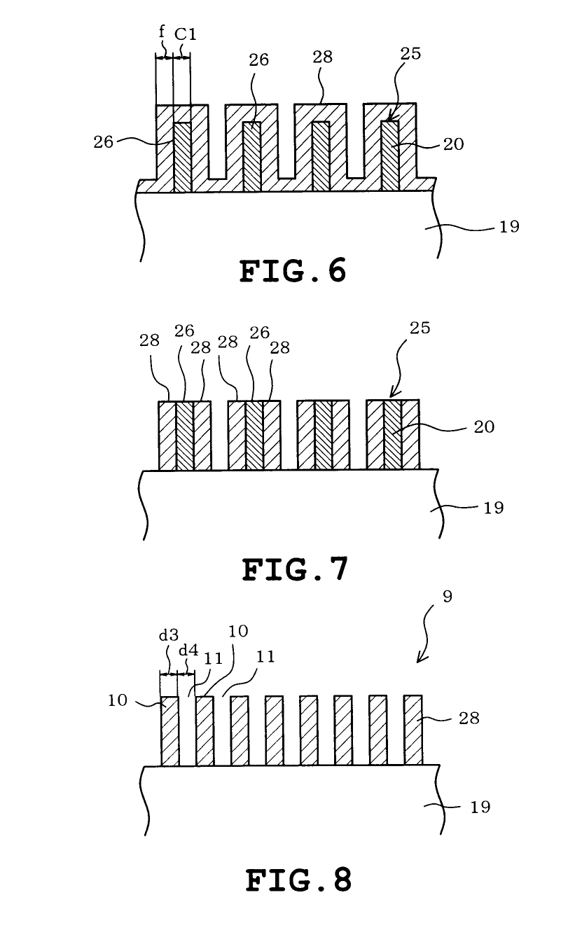

Next, as shown in FIG. 6, film 28 is deposited by LP-CVD (Low Pressure Chemical Vapor Deposition) above the patterned sacrificial film 20, i.e. L/S pattern 25. Film 28 is deposited at thickness f which is equal to width c1 of line 26 of L/S pattern 25. As can be seen in FIG. 6, thickness of film 28 is controlled such that at least the portion overlying the sidewalls of lines 26 is as thick as width c1 of line 26, i.e. f=c1. Film 28 typically comprises silicon nitride film or the like that possesses high etching selectivity to sacrificial film 20.

Then, film 28 is etched back as shown in FIG. 7 such that film 28 remains as sidewall film 28 over line 26 of L/S pattern 25. Thereafter, line 26 between sidewall film 28 is removed as shown in FIG. 8 to obtain L/S mask pattern 9 having sidewall film 28 located above semiconductor substrate 19 as shown in top view in FIG. 1.

FIG. 8 shows L/S pattern 9 having lines 10 of width d3 and spaces 11 of width d4 where width 3 equals width d4. Width d3 and width d4 are 1/2 the measurements of corresponding width d1 and d2 of lines 2 and spaces 3 of resist pattern 1 indicated in FIGS. 2 and 3.

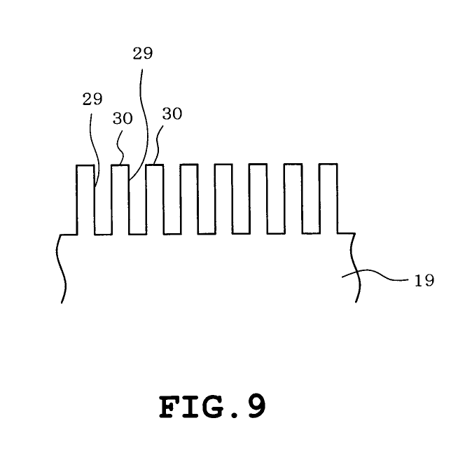

Then, using L/S pattern 9 of FIG. 8 as a mask, semiconductor substrate 19 is etched by RIE to define element isolation trenches 29 whereby active regions 30 are isolated as can be seen in FIG. 9. Element isolation trenches 29 are then filled with an element isolation insulating film to obtain an element isolation region.

According to the above described first embodiment, the first and the second lines 10 and 11 counted from the left and right side ends are each separated into three line segments 13, 15, 17, and 14, 16, 18 as can be seen in FIG. 1. Further, the lower ends of the two uppermost line segments 13 and 14 are linked by linking pattern 12 and the upper end of the uppermost line segments 14 is linked with the upper end of the third line 10 counted from the left end by linking pattern 12. The upper and lower ends of the two middle line segments 15 and 16 are linked together by linking pattern 12. The upper ends of two lowermost line segments 17 and 18 are linked by linking pattern 12 and the lower end of the lowermost line segment 18 is linked with the lower end of the third line 10 counted from the left side end by linking pattern 12.

According to the above described configuration, the length of the first line 10, represented as line segments 13, 15, 17, counted from the left and the right side ends of the memory cell region can be significantly reduced to approximately ⅓. At the same time, the two segmented lines 10 are linked by link pattern 12 formed by the SWT process to form a looped structure, thereby allowing the two segmented lines 10 to support each other. As a result, the first line 10 counted from the left and right side ends of the memory cell region can be sufficiently collapse resistant to tolerate collapse and/or twists which was conventionally observed in the dry etching or wet processing performed during the manufacturing process flow of the memory cell region.

According to the first embodiment, the first ten to twenty lines 10 of active regions 30 counted from the left and right sides of the memory cell region is a dummy region which is not available as memory cells. Thus, the presence of the above described looped structure linking the neighboring first and second lines 10 or the later described active regions 30 will not affect device performance/operation. As described earlier, the loop is formed by the SWT process and typically comprises two neighboring line segments and linking pattern 12 linking the two neighboring line segments at their segment ends. The two opposing loops of the neighboring lines 10 constitute a separation site of the neighboring lines 10.

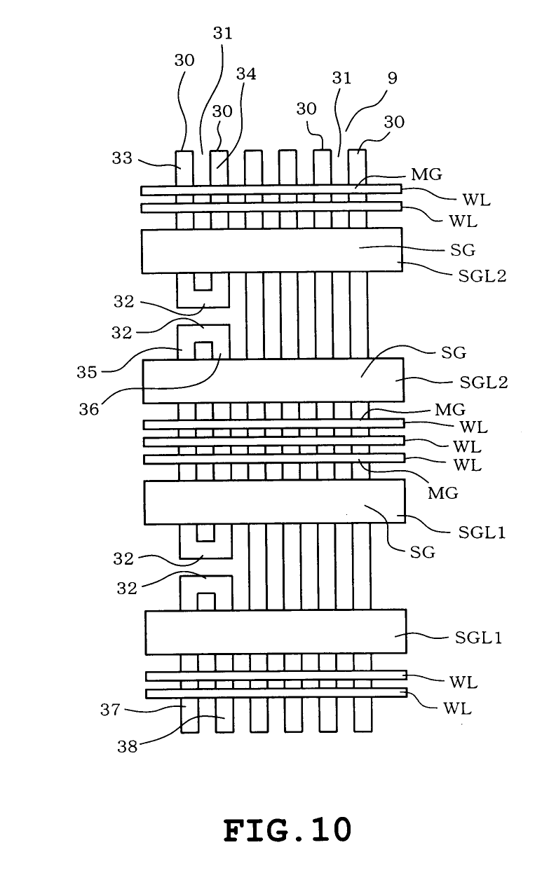

FIG. 10 illustrates a second embodiment of the present disclosure. As can be seen in FIG. 10, active regions 30 and element isolation regions 31 are formed in semiconductor substrate 19 based on L/S mask pattern 9 using SWT process discussed in the first embodiment, meaning that lines 10 and spaces 11 are transferred to semiconductor substrate 19 as active regions 30 and element isolation regions 31, respectively. FIG. 10 further shows word lines WL of memory cell transistors and select gate lines SGL1 and SGL2 of select transistors crossing perpendicularly over active regions 30. The memory cell transistors are formed at the cross over of word line WL and active regions 30, and the memory cell transistors are provided with gate electrodes MG. The select transistors are formed at the cross over of select gate lines SGL1/SGL2 and active regions 30, and the select transistors are provided with gate electrodes SG.

Word lines WL and active regions 30 are arranged in a matrix of rows and columns in which thirty two rows of word lines WL are bundled into a single NAND string within a column of active region 30 in the second embodiment. FIG. 10 only shows three word lines WL within a single NAND string. In another embodiment, a single NAND string may contain 64 word lines WL. A pair of select gate lines SGL1 and SGL2 are located at the two longitudinal ends of each NAND string such that the 32 or 64 word lines WL run between the pair of select gate lines SGL1 and SGL2. Either of select gate lines SGL1 and SGL2 are located in the source side and the remaining other is located in the drain side. The NAND strings are arranged such that select gate line SGL1/SGL2 of a given NAND string within a given column of active region 30 opposes another select gate line SGL1/SGL2 of the neighboring NAND string within the same column of active region 30. Thus, select gate line SGL1 of one NAND string opposes select gate line SGL1 of the neighboring NAND string to form an opposing pair of select gate lines SGL1, whereas select gate line SGL2 of one NAND string opposes select gate line SGL2 of the neighboring NAND string to form an opposing pair of select gate lines SGL2 as can be seen in FIG. 3. In active region 30 located between the opposing pair of select gate lines SGL1/SGL2, a source line contact not shown is disposed to allow the source line contact to be shared between the two neighboring NAND strings. Likewise, in active region 30 located between the opposing pair of select gate lines SGL2/SGL1, a bit line contact not shown is disposed to allow the bit line contact to be shared between the two neighboring NAND strings.

As described above, the source and drain of the NAND strings are alternately reversed to allow the two neighboring NAND string within the same column of active region 30 to share the bit line contact and the source line contact. This arrangement is repeated throughout the columns of active regions 30 to define a memory cell array.

According to the second embodiment, each of the separation sites of the first and second columns/lines of active regions 30 counted from the left side end of the memory cell region shown in FIG. 10 is located between the opposing pair of select gate lines SGL1/SGL2. The above described first and second columns/lines of active regions 30 of the memory cell region correspond to the first and second lines 10 of L/S pattern 9 discussed in the first embodiment. Each of the columns/lines constituting active regions 30 will also be referred to as line 30 hereinafter for ease of explanation. The first and second lines 30 are each separated into three line segments 33, 35, 37 and 34, 36, 38, respectively. The foregoing line segments correspond to line segments 13, 15, 17 and 14, 16, 18 of L/S pattern 9 discussed in the first embodiment. The segment ends of line segments 33 and 34, line segments 35 and 36, and line segments 37 and 38 are linked into loops by linking patterns 32 as shown in FIG. 10. Linking pattern 32 corresponds to linking pattern 12 formed by SWT process in the first embodiment. As described in the first embodiment, the opposing loops of the neighboring lines, in this case, the first and the second lines 30 constitute the separation site. According to the second embodiment, each of the separation sites are located between the opposing pair of select gate lines SGL1/SGL2 as can be seen in FIG. 10. Though FIG. 10 is a partial representation of the left side end of the memory cell region, the right side end is configured in the same manner.

The elements not described above remain unchanged from the first embodiment. Thus, the second embodiment provides similar advantages to those provided in the first embodiment. According to the second embodiment, the separation sites are located between the opposing pairs of select gate lines SGL1/SGL2 which are spaced wider than the neighboring word lines WL. According to the above described configuration, cuts 5 formed in line 2 of resist pattern 1 for forming looped linking patterns 32 may introduce variation in the length of line 2 located at the left and the right side end of resist pattern 1. However, because the loops are located between opposing pairs of select gate lines SGL1/SGL2 which are spaced wider than the neighboring word lines WL, dimension variance, if any, will not lead to displacement of active regions 30, word lines WL, and select gate lines SGL1/SGL2 that may negatively impact device performance and operation.

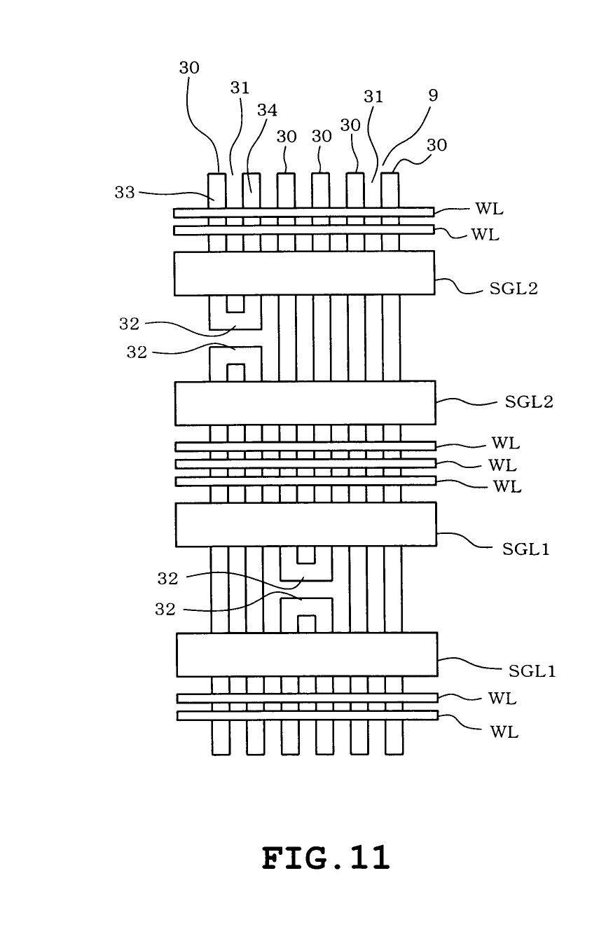

FIG. 11 illustrates a third embodiment of the present disclosure. Elements that are identical with those of the second embodiment are represented by identical reference symbols. According to the third embodiment, the first and second lines 30 counted from the left side end of the memory cell region shown in FIG. 11 are provided with a single separation site. Similarly, the third and fourth lines 30 are provided with a single separation site. Each separation site, is located between the opposing pair of select gate lines SGL1/SGL2. Though FIG. 11 is a partial representation of the left side end of the memory cell region, the right side end is configured in the same manner.

The elements not described above remain unchanged from the second embodiment. Thus, the third embodiment provides similar advantages to those provided in the second embodiment.

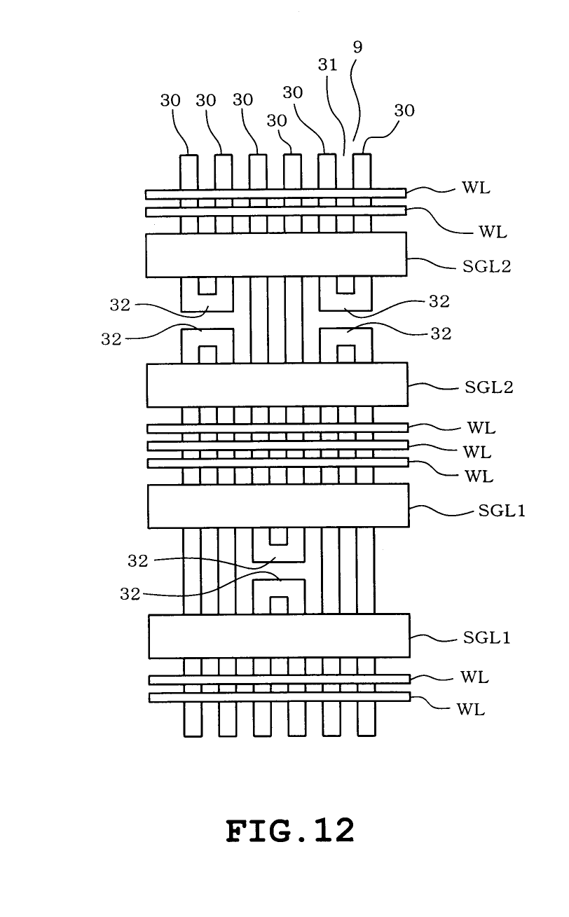

FIG. 12 illustrates a fourth embodiment of the present disclosure. Elements that are identical with those of the third embodiment are represented by identical reference symbols. According to the fourth embodiment, the first and second lines 30 counted from the left side end of the memory cell region shown in FIG. 12 are provided with a single separation site. Similarly, the third and fourth lines 30 are provided with a single separation site. Further, the fifth and sixth lines 30 are provided with a single separation site.

Each separation site is located between the opposing pair of select gate lines SGL1/SGL2. Though FIG. 12 is a partial representation of the left side end of the memory cell region, the right side end is configured in the same manner.

The elements not described above remain unchanged from the third embodiment. Thus, the fourth embodiment provides similar advantages to those provided in the third embodiment.

The foregoing embodiments may be modified or expanded as follows.

The first and the second embodiments may be modified such that the two separation sites provided across the first and the second lines 30 counted from the left and right side ends of the memory cell region are reduced to one or increased to three or more.

According to the second embodiment, two separation sites are provided across the first and the second lines 30 counted from the left and right side ends of the memory cell region so as to be located between the opposing pair of select gate lines SGL1 and between the opposing pair of select gate lines SGL2. Alternatively, the separation sites may be increased in number such that a separation site is located between every opposing pairs of select gate lines SGL1 and between every opposing pairs of select gate lines SGL2. Still alternatively, the separation sites may be located between some of the opposing pairs of select gate lines SGL1 and between some of the opposing pairs of select gate lines SGL2.

According to the third embodiment, one separation site is located across the first and the second lines 30 counted from the left and right side ends of the memory cell region and across the third and fourth lines 30, respectively, so as to be located between the opposing pair of select gate lines SGL1/SGL2. Alternatively, the separation sites may be increased in number such that a separation site is located between every opposing pair of select gate lines SGL1 and between every opposing pair of select gate lines SGL2 for the first to fourth lines 30. Still alternatively, the separation sites may be located between some of the opposing pairs of select gate lines SGL1 and between some of the opposing pairs of select gate lines SGL2 for the first to fourth lines 30.

According to the fourth embodiment, one separation site is located across the first and the second lines 30 counted from the left and right side ends of the memory cell region, across the third and fourth lines 30, and across the fifth and sixth lines 30, respectively, so as to be located between the opposing pair of select gate lines SGL1/SGL2. Alternatively, the separation sites may be increased in number such that a separation site is located between every opposing pair of select gate lines SGL1 and between every opposing pair of select gate lines SGL2 for the first to sixth lines 30. Still alternatively, the separation sites may be located between some of the opposing pairs of select gate lines SGL1 and between some of the opposing pairs of select gate lines SGL2 for the first to sixth lines 30. Still further, one or more separation sites may be provided across two lines 30 located from the seventh line 30 or later lines counted from the left and right side ends of the memory cell region so as to be located between the opposing pair of select gate lines SGL1/SGL2.

The semiconductor device according to the foregoing embodiments is configured such that among the lines constituting the active regions, at least the first and the second lines counted from the left and right side ends of the memory cell region of the memory cell are separated into two or more segments and the segment ends of the two lines are linked into a loop. Thus, the lines located at the left and right side ends of the memory cell region can be prevented from collapsing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor substrate;
a memory cell region defined in the semiconductor substrate; and
a line-and-space pattern formed in the memory cell region in which the lines constitute an active region and the spaces constitute an element isolation region,
wherein the first and the second lines of the active region counted from two opposing ends of the memory cell region are each separated into two or more line segments, and
wherein segment ends of the line segments of the first and the second lines are linked to form a loop by a linking pattern.

2. The device according to claim 1, wherein the first and the second lines each has two separation sites.

3. The device according to claim 1, wherein the first and the second lines each has three or more separation sites.

4. The device according to claim 1, wherein two neighboring lines of the active region located in the third or later lines counted from the two opposing ends of the memory cell region are each separated into two or more line segments, and segment ends of the line segments of the two neighboring lines are linked into a loop by the linking pattern.

5. The device according to claim 4, wherein the third and the fourth lines of the active region counted from the two opposing ends of the memory cell region are each separated into two or more line segments.

6. The device according to claim 5, wherein the fifth and the sixth lines of the active region counted from the two opposing ends of the memory cell region are each separated into two or more line segments.

7. The device according to claim 1, further comprising a plurality of word lines that crosses perpendicularly with the active region and that interconnects memory cell transistors formed in the active region, and a plurality of select gate lines that crosses perpendicularly with the active region and that interconnects select transistors formed in the active region, wherein a separation site of the first and the second lines are located between one or more pairs of the select gate lines.

8. The device according to claim 7, wherein the first and the second lines each has a plurality of separation sites such that the separation sites are located between every pair of select gate lines.

9. The device according to claim 7, wherein the first and the second lines each has a plurality of separation sites such that the separation sites are located between some pairs of the select gate lines.

10. The device according to claim 4, further comprising a plurality of word lines that crosses perpendicularly with the active region and that interconnects memory cell transistors formed in the active region, and a plurality of select gate lines that crosses perpendicularly with the active region and that interconnects select transistors formed in the active region, wherein the one or more separation sites of the first and the second lines are located between one or more pairs of select gate lines, and wherein the one or more separation sites of two neighboring lines of the active region located in the third or later lines counted from the two opposing ends of the memory cell region are located between one or more pairs of select gate lines.

11. The device according to claim 10, wherein the first and the second lines each has a single separation site located between a first pair of select gate lines, and wherein the third and the fourth lines each has a single separation site located between a second pair of select gate lines.

12. The device according to claim 10, wherein the first and the second lines each has a plurality of separation sites such that the separation sites are located between every pair of select gate lines, and wherein the third and the fourth lines each has a plurality of separation sites such that the separation sites are located between every pair of the select gate lines.

13. The device according to claim 10, wherein the first and the second lines have a plurality of separation sites such that the separation sites are located between some pairs of the select gate lines, and wherein the third and the fourth lines have a plurality of separation sites such that the separation sites are located between some pairs of the select gate lines.

14. The device according to claim 10, wherein the first and the second lines each has a single separation site located between a first pair of the select gate lines, and wherein the third and the fourth lines each has a single separation site located between a second pair of the select gate lines, and wherein the fifth and the sixth lines each has a single separation site located between the first pair of the select gate lines.

15. The device according to claim 10, wherein the first and the second lines each has a plurality of separation sites such that the separation sites are located between every pair of the select gate lines, and wherein the third and the fourth lines each has a plurality of separation sites such that the separation sites are located between every pair of the select gate lines, and wherein the fifth and the sixth lines each has a plurality of separation sites such that the separation sites are located between every pair of the select gate lines.

16. The device according to claim 10, wherein the first and the second lines each has a plurality of separation sites such that the separation sites are located between some pairs of the select gate lines, wherein the third and the fourth lines each has a plurality of separation sites such that the separation sites are located between some pairs of the select gate lines wherein the fifth and the sixth lines each has a plurality of separation sites such that the separation sites are located between some of pairs of the select gate lines.

17. A method of manufacturing a semiconductor device comprising:
forming a sacrificial film above a semiconductor substrate;
forming a resist film above the sacrificial film;
patterning the resist film into a first line-and-space pattern in which widths of both the lines and spaces are equal;
slimming the width of the lines in half to form a second line-and-space pattern;
transferring the second line-and-space pattern to the sacrificial film using the resist film as a mask to form a third line-and-space pattern in the sacrificial film;
removing the resist film;
forming a sidewall film on sidewalls of the lines of the third line-and-space pattern;
removing the sacrificial film to form a fourth line-and-space pattern; and
transferring the fourth line-and-space pattern to the semiconductor substrate using the sidewall film as a mask;
wherein forming the resist film forms one or more cuts in the first line of the first line-and-space pattern counted from opposing ends of a memory cell region to separate the first line into a plurality of segments.

18. The method according to claim 17, wherein forming the resist film forms one or more cuts in one or more lines of the first line-and-space pattern located in the second or later lines counted from opposing ends of the memory cell region to separate the one or more lines into a plurality of segments.

19. The method according to claim 17, wherein transferring the fourth line-and-space pattern to the semiconductor substrate includes:
forming an active region in the memory cell region based on the lines of the fourth line-and-space pattern,
forming an element isolation region in the memory cell region based on the spaces of the fourth line-and-space pattern,
forming a plurality of word lines crossing perpendicularly over the active region, each word line interconnecting memory cell transistors formed in the active region, and
forming a plurality of select gate lines crossing perpendicularly over the active region, each select gate line interconnecting select transistors formed in the active region,
wherein the one or more cuts formed in the first line is located between one or more pairs of the select gate lines.

20. The method according to claim 18, wherein transferring the fourth line-and-space pattern to the semiconductor substrate includes:
forming an active region in the memory cell region based on the lines of the fourth line-and-space pattern,
forming an element isolation region in the memory cell region based on the spaces of the fourth line-and-space pattern,
forming a plurality of word lines crossing perpendicularly over the active region, each word line interconnecting memory cell transistors formed in the active region, and
forming a plurality of select gate lines crossing perpendicularly over the active region, each select gate line interconnecting select transistors formed in the active region,
wherein the one or more cuts formed in the first line is located between one or more pairs of the select gate lines, and the one or more cuts formed in the one or more lines located in the second or later lines are located between one or more pairs of the select gate lines.
